(19) United States
(12) Patent Application Publication
(10) Pub. No.: US 2026/0290714 A1
(43) Pub. Date: Sep. 24, 2026

(54) BROADBAND RADIO FREQUENCY MICRO-ACTUATOR SWITCH WITH HIGH ISOLATION

(71) Applicant: Dell Products L.P., Round Rock, TX (US)

(72) Inventors: Tejinder Singh, Manotick (CA); Navjot Kaur Khaira, Manotick (CA)

(21) Appl. No.: 19/085,884

(22) Filed: Mar. 20, 2025

(51) Int. Cl. H01H 1/00; B81B 3/00; B81B 7/00

(52) U.S. Cl. CPC H01H 1/0036; B81B 3/0086; B81B 7/0006; B81B 2201/014; B81B 2203/0118; H01H 2001/0084; H01H 2001/0089

(57) ABSTRACT

The technology described herein is directed towards a broadband (e.g., DC-40 GHz) micro-actuator-based radio frequency (RF) switch, which results in high-isolation by connecting two micro-cantilevers, such as in a back-to-back configuration. This design facilitates highly suitable RF performance, while also reducing the actuation voltage applied to achieve electrostatic operation. The micro-actuator-based switch is thus appropriate for applications that specify high RF signal integrity and low power. The design utilizes through-substrate interconnects to supply actuation power as DC voltage for electrostatic actuation, thereby reducing any DC to RF interference. The micro-actuator-based switch is compact, which along with high isolation and efficient electrostatic actuation, is suitable for integration in advanced RF frontends and reconfigurable networks, including high-density communication environments.

### RELATED APPLICATIONS

The subject patent application is related to U.S. patent application Ser. No. ______, filed ______, and entitled “SWITCH MATRIX WITH HIGH RADIO FREQUENCY ISOLATION UTILIZING DUAL MECHANICAL MICRO-MEMBRANE ACTUATORS” (docket no. 141546.01/DELLP1474US), and U.S. patent application Ser. No. ______, filed ______, and entitled “SCALABLE RADIO FREQUENCY SWITCH MATRIX FOR MULTIPORT SIGNAL ROUTING” (docket no. 141548.01/DELLP1479US), the entireties of which patent applications are hereby incorporated by reference herein.

### BACKGROUND

As radio frequency systems evolve and advance, high isolation and compact devices are sought after to maintain signal integrity, especially in environments with high-density communication requirements. Existing devices often struggle with maintaining high isolation (e.g., with respect to low signal leakage or crosstalk) without compromising on size and performance, limiting their integration into compact systems. Typical device performance parameters include insertion loss, switching speed, actuation voltage, and reliability.

### BRIEF DESCRIPTION OF THE DRAWINGS

The technology described herein is illustrated by way of example and not limited in the accompanying figures in which like reference numerals indicate similar elements and in which:

FIGS. 1A and 1B are side views of an example micromembrane actuator showing the general operating principle (open, FIG. 1A, and closed, FIG. 1B) via a cantilever-based connector, in accordance with various example embodiments and implementations of the subject disclosure.

FIGS. 2A and 2B show a general semitransparent layout and top view, respectively, of an example dual-cantilever micromembrane actuator device, in accordance with various example embodiments and implementations of the subject disclosure.

FIG. 3 is an isometric top view representation of an example dual-cantilever micromembrane actuator device, in accordance with various example embodiments and implementations of the subject disclosure.

FIG. 4 is an isometric bottom view representation of one example dual-cantilever micromembrane actuator device, showing control contact pads with voltages applied by a controller, in accordance with various example embodiments and implementations of the subject disclosure.

FIG. 5 is a cross-section view representation of one example dual-cantilever micromembrane actuator device, in accordance with various example embodiments and implementations of the subject disclosure.

FIG. 6 is an isometric side and top view representation showing various components of one example dual-cantilever micromembrane actuator device, in accordance with various example embodiments and implementations of the subject disclosure.

FIG. 7A is an enlarged view representation of part of the dual-cantilever micromembrane actuator device of FIG. 6, in accordance with various example embodiments and implementations of the subject disclosure

FIG. 7B is an isometric side and bottom view representation showing various components of one example dual-cantilever micromembrane actuator device, in accordance with various example embodiments and implementations of the subject disclosure.

FIG. 8 is an example graphical representation of dimples (electrical contact tips) and mid-plane displacement (in micrometers, or μm) for different levels of applied voltage (Volts, in V) to an example cantilever micromembrane actuator device, in accordance with various example embodiments and implementations of the subject disclosure.

FIGS. 9A, 9B 9C, 10A, 10B and 10C are side views of an example top-side additive manufacturing process as layers are added (and a sacrificial layer removed) during fabrication, in accordance with various example embodiments and implementations of the subject disclosure.

FIGS. 11A and 11B are example graphical representations of RF performance simulation results for an example dual-cantilever micromembrane actuator device, including return loss performance (FIG. 11A) and isolation performance (FIG. 11B), in accordance with various example embodiments and implementations of the subject disclosure.

FIG. 12 is a flow diagram showing example operations related to actuating an example dual-actuator switch including by applying two voltages to deform dual cantilevers, in accordance with various example embodiments and implementations of the subject disclosure.

### DETAILED DESCRIPTION

The technology described herein is generally directed towards a high-isolation broadband DC-40 GHz micro-actuator-based switch, aimed at improving isolation performance in radio frequency (RF) systems. In one implementation, this is accomplished by connecting (at least) two micro-cantilevers, (e.g., metal micromembrane cantilevers) such as in a back-to-back configuration. This configuration enhances RF performance along with reducing the actuation voltage used for electrostatic operation, which results in high RF signal integrity and low power.

As will be understood, the result is a high isolation switch device suitable for integration into compact systems, which is unlike existing switch designs that often struggle with maintaining high isolation, and/or have to compromise on size and performance, thereby limiting integration of existing switch designs into compact systems. Instead, the switch technology described herein provides high isolation, compactness, and efficient electrostatic actuation.

The micro-actuator-based switch configuration employing dual (e.g., back-to-back) micro-cantilevers enhances RF performance, along with reducing the actuation voltage for electrostatic operation. To enhance RF performance, the design increases the overall vertical distance between RF lines and contact points, which generally gets smaller due to residual stresses after releasing the cantilever beams during fabrication. The micro-actuator-based switch configuration also lowers the actuation voltage via a lower gap, which generates sufficient pull-in force between the membrane and electrode, making the device well-suited for applications demanding high signal integrity. Through-substrate interconnects provide DC power for the electrostatic actuation, allowing relatively precise control over switch states while minimizing any DC to RF interference. The design also offers a compact form factor for integration in small space, high performance RF systems.

It should be understood that any of the examples and/or descriptions herein are non-limiting. Thus, any of the embodiments, example embodiments, concepts, structures, functionalities or examples described herein are non-limiting, and the technology may be used in various ways that provide benefits and advantages in communications and computing in general.

Reference throughout this specification to “one embodiment,” “an embodiment,” “one implementation,” “an implementation,” etc. means that a particular feature, structure, characteristic and/or attribute described in connection with the embodiment/implementation can be included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, characteristics and/or attributes may be combined in any suitable manner in one or more embodiments/implementations. Repetitive description of like elements employed in respective embodiments may be omitted for sake of brevity.

The detailed description is merely illustrative and is not intended to limit embodiments and/or application or uses of embodiments. Furthermore, there is no intention to be bound by any expressed or implied information presented in the preceding sections, or in the Detailed Description section. Further, it is to be understood that the present disclosure will be described in terms of a given illustrative architecture; however, other architectures, structures, materials and process features, and steps can be varied within the scope of the present disclosure.

It also should be noted that terms used herein, such as “optimize,” “optimization,” “optimal,” “optimally” and the like only represent objectives to move towards a more optimal state, rather than necessarily obtaining ideal results. Similarly, “maximize” means moving towards a maximal state (e.g., up to some processing capacity limit), not necessarily achieving such a state, and so on.

It will also be understood that when an element such as a layer, region or substrate is referred to as being “on” or “over” “atop” “above” “beneath” “below” and so forth with respect to another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

The following detailed description is merely illustrative and is not intended to limit embodiments and/or application or uses of embodiments. Furthermore, there is no intention to be bound by any expressed or implied information presented in the preceding sections, or in the Detailed Description section.

One or more example embodiments are now described with reference to the drawings, in which example components, graphs and/or operations are shown, and in which like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details, and that the subject disclosure may be embodied in many different forms and should not be construed as limited to the examples set forth herein.

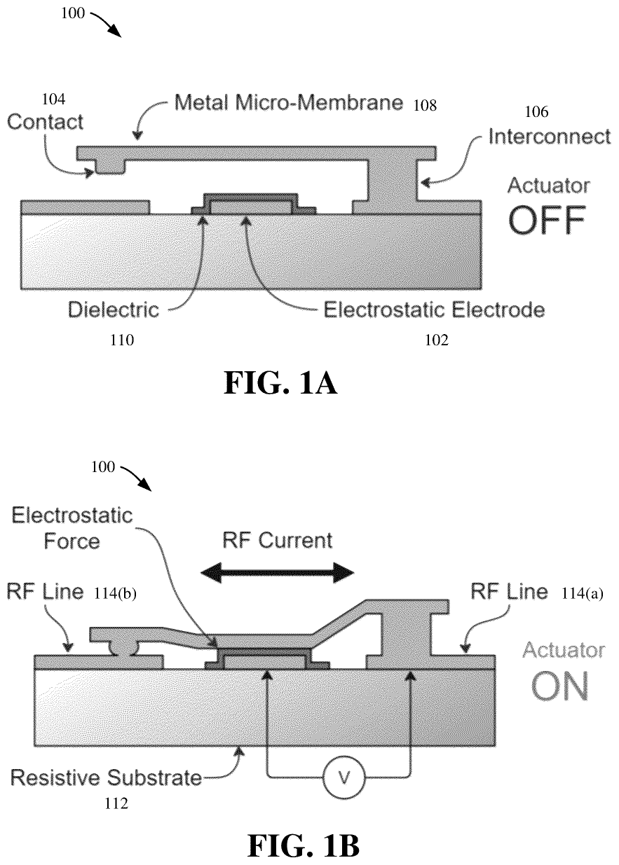

FIG. 1A shows an example cantilever type micromembrane actuator 100 in an actuator OFF State, and FIG. 1B shows the example cantilever type micromembrane actuator 100 in an actuator ON state. When no voltage (or too low of a voltage to actuate) is applied to the electrostatic electrode 102 as in FIG. 1A, the micromembrane's contact 104 remains in a lifted state due to the structural configuration of the metal micromembrane 108. In this OFF state, RF current (e.g., obtained an interconnect 106) cannot flow across the RF line, effectively isolating the circuit.

FIG. 1B shows electrostatic actuation, in which applying a voltage V difference to the electrode (relative to ground) creates an electrostatic force that pulls the micromembrane 108 down towards the resistive substrate 112. This electrostatic force overcomes the membrane's structural tension, bringing its contact 104 into contact with the RF line 114(b) at its non-anchored end. In this actuator ON state, the electrical coupling between the micromembrane and RF line is established, allowing RF current to pass through. The RF signal can then flow across the circuit, enabling connectivity between the RF lines 114(a) and 114(b). Note that FIG. 1 shows a dielectric 110 that electrically insulates the electrostatic electrode 102 from the RF lines 114(a) and 114(b).

One example implementation of a micro-actuator-based switch solution as described herein includes a micro-actuator-based switch that enhances isolation by connecting two micro-cantilevers back-to-back. This back-to-back configuration significantly increases isolation performance by increasing the overall vertical distance between RF lines and contact points, which generally gets less due to residual stresses after releasing the cantilever beams. This micro-actuator-based switch configuration also lowers the actuation voltage whereby a lower gap is needed to generate sufficient pull-in force between the membrane and the electrode, making it well-suited for applications demanding high signal integrity. Through-substrate interconnects provide DC power for the electrostatic actuation, allowing precise control over switch states. The design also offers a compact form factor, ideal for integration in RF systems where space and performance are significant considerations.

In general, micromembrane actuators enable relatively highly precise, relatively low loss switching in RF systems, offering a reliable alternative to traditional semiconductor and mechanical switches. Their ability to toggle at high-speed with minimal loss, linearity, and high-power handling makes them suitable for reconfigurable antennas, tunable filters, and multi-band communication systems. Note that other, common types of switch configurations include electrostatic, piezoelectric, and thermal actuation switches; each type has certain advantages in terms of speed, power consumption, and mechanical stability. Electrostatic actuators are used due to their low power consumption and rapid actuation.

Further note that while micromembrane actuators were evaluated in the past decade due to their ON-state performance, with micro-scale cantilevers having curvature after manufacturing, in prior micromembrane actuators the isolation performance suffers. Indeed, conventional switch designs, such as microelectromechanical systems (MEMS) switches, face limitations in isolation performance, especially when subjected to high-frequency applications. Moreover, standard MEMS based cantilever solutions also suffer from residual stresses from manufacturing, leading to poor isolation performance. Such designs typically have performance pitfalls from leakage and insufficient isolation, reducing overall system effectiveness. While stacked designs can improve isolation, they often increase complexity and size, which are complex to manufacture and have poor reliability issues.

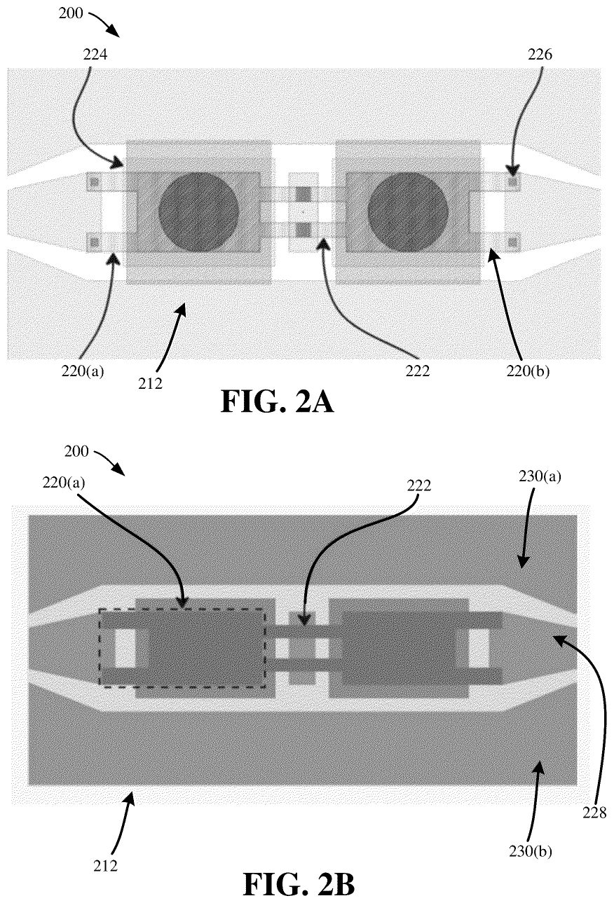

FIGS. 2A and 2B show an example layout and top view, respectively, of a dual micro-actuator-based switch device fabricated on a substrate 212. As can be seen, in this example implementation, two micromembranes 220(a) and 220(b) are connected back to and anchored (back-to-back connected anchors 222) on an isolated metal island (one of which is labeled 224, RF disconnected).

In this example implementation, dual metal contacts (one of which is labeled 226) are at the forked ends of the cantilever micromembranes. The RF signal line input-to-output (or vice-versa) port 228 (shown between two RF ground regions 230(a) and 230(b)) is connected by actuating both the actuators in conjunction with one another; note that individual voltage contact pads are designed to compensate for different manufacturing tolerances of residual stress by allowing different, individual voltages to be applied to deform each micromembrane as needed for a given micromembrane displacement. The amount of electrostatic pull-in force is generated by each DC voltage to switch the device to its ON state; removal of the voltage, which can include sufficiently lowering the voltage to zero or near-zero volts, switches the device to its OFF state. Although it is feasible to de-actuate only one micromembrane to disconnect the RF line, improved isolation is achieved by de-actuating both micromembranes together relative to de-actuating only one. As will be understood, such an example design results in a dual broadband in-line micro-actuator-based switch with excellent RF performance over DC to (at least) 40 GHz.

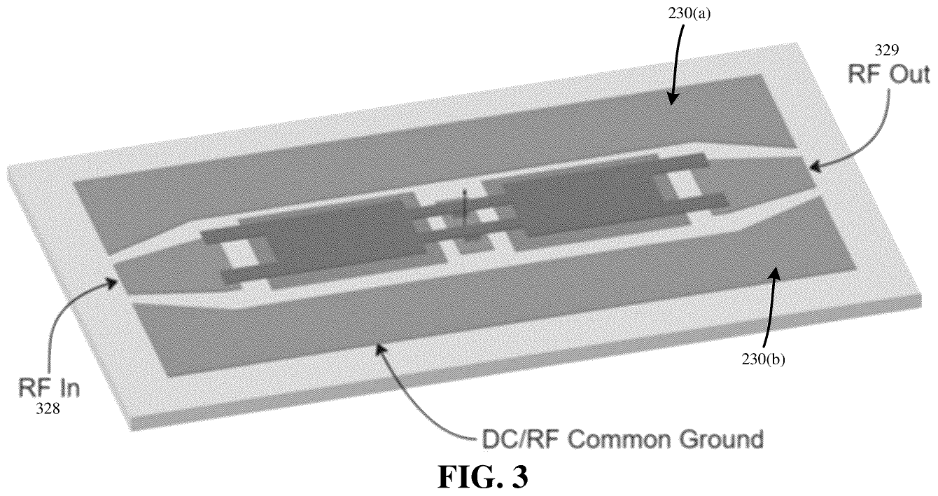

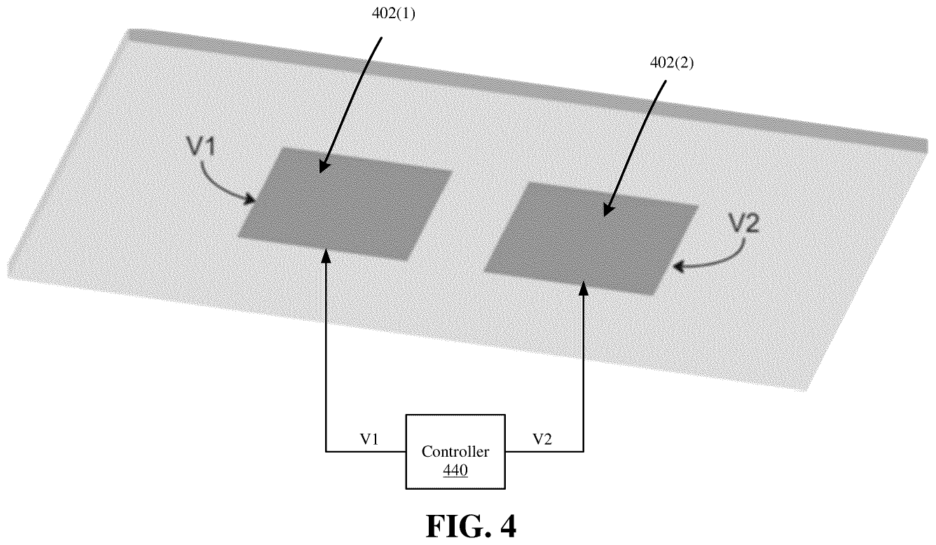

FIGS. 3 and 4 are top and bottom isometric views of the micro-actuator-based switch device 200 depicting an RF-input port 328 and RF output port 329 shown between the two RF ground regions 230(a) and 230(b)). Note that the DC voltage bias can share the RF common ground, with the positive voltages V1 and V2 applied to the two voltage contact pads 402(1) and 402(2) coupled to the electrostatic electrodes, as shown in FIG. 4. A controller 440 can controllably apply the voltages V1 and V2, which may differ as described herein, to actuate the micromembranes to provide the RF signal path, and controllably remove the voltages V1 and V2 to de-actuate the micromembranes.

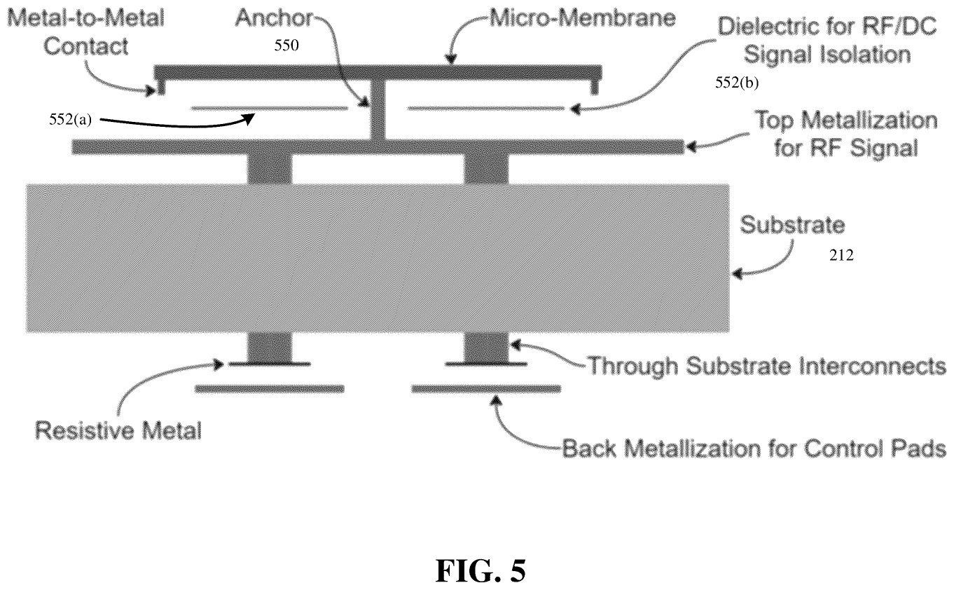

FIG. 5 is a cross-sectional view of an example dual micro-actuator-based switch device. In this design, a shared anchor 550 is positioned between the dual micromembrane portions. Dielectric materials 552(a) and 552(b) beneath the micromembrane portions help with RF signal isolation.

Two interconnects through the substrate carry the voltage through the contact pads to the electrostatic electrodes. In this implementation, resistive material is between the contact pads and the electrostatic electrodes, so that the electrostatic energy is appropriate for actuation.

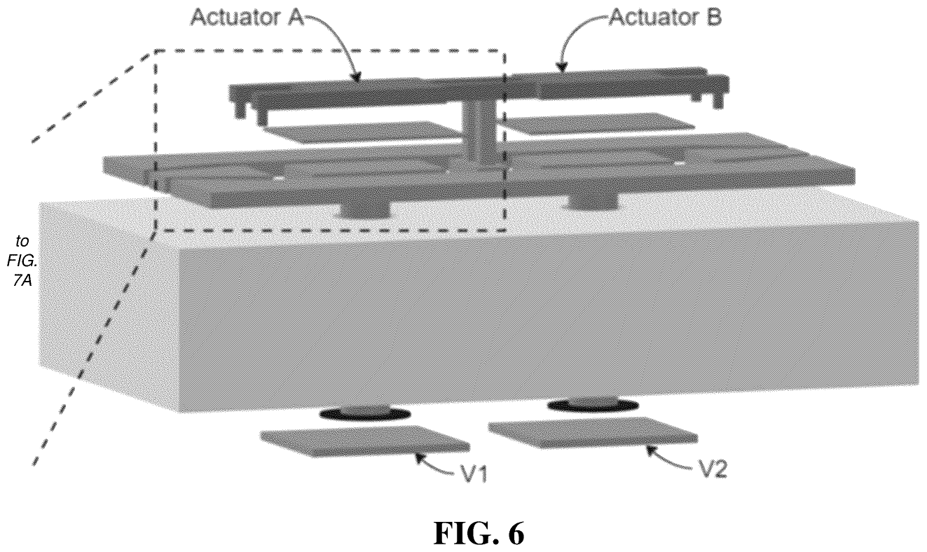

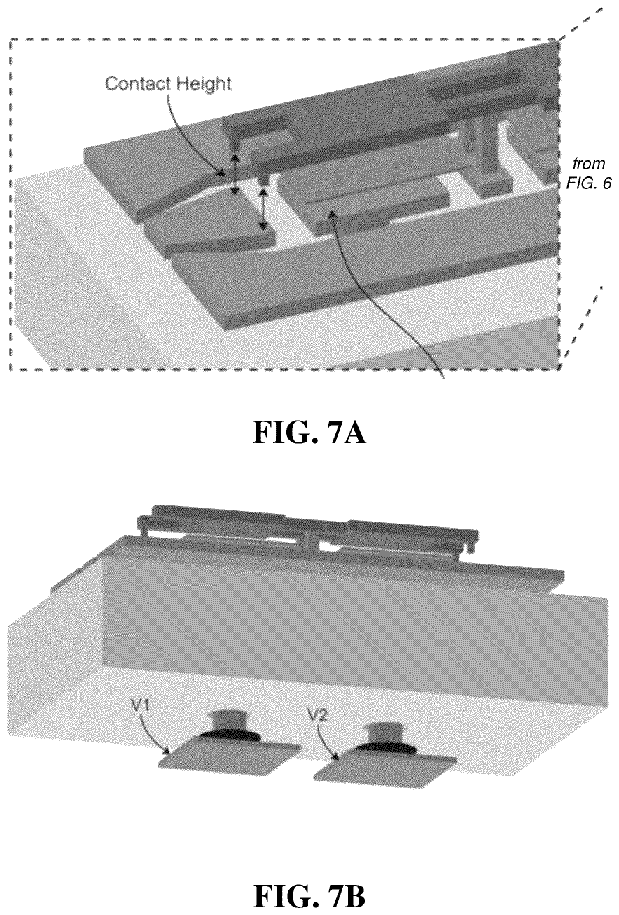

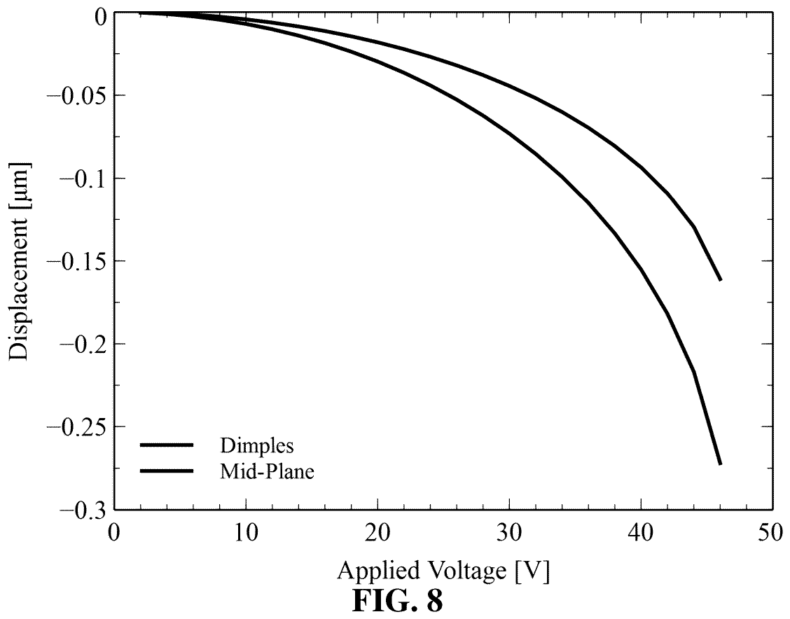

As shown in FIGS. 6, 7A and 7B, the shared anchor can be a set of two anchors, and the RF coupling contacts/dimples can number at least two. The contact height difference can be designed to save power by having only a relatively small amount of energy (voltage) applied to actuate the cantilevers.

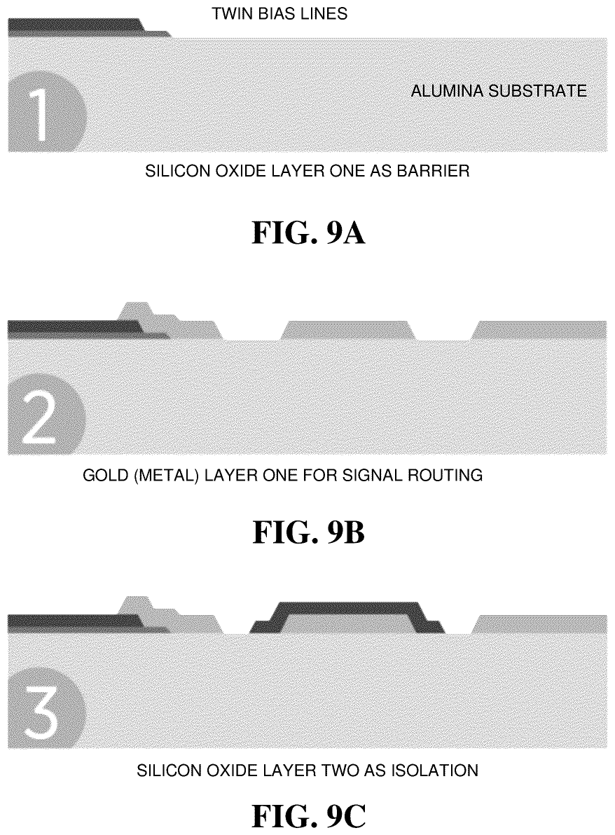

For example, FIG. 8 shows a full-field simulation performed in Ansys Mechanical for different V1 voltages applied between the V1 contact pad and common ground. Deflection is monitored at mid-plane and at the contacts/dimples, showing negative (downward) displacement distances on the order of a relative few micrometers.

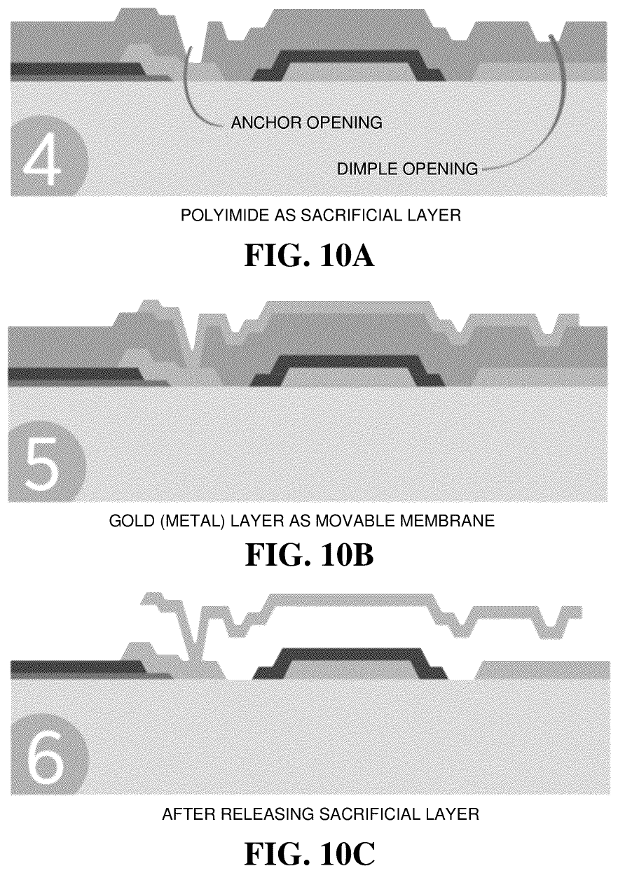

FIGS. 9A, 9B 9C, 10A, 10B and 10C are side views of one example top-side additive manufacturing process. A multiple (e.g., six in this example) step micro-fabrication process has been developed for the micro-actuator-based switch device. Through substrate interconnects and back-side processing can be carried out as a post-processing step. Example material choices are depicted in the process cross-sections shown, but as is understood, any suitable materials can be substituted as appropriate for a given application.

FIG. 9A shows twin bias lines atop an alumina substrate, with a first silicon oxide layer (layer one) as a barrier. In FIG. 9B, a gold (or another suitable metal) layer, (metal layer one), is applied for signal routing. In FIG. 9C, a second silicon oxide layer (layer two) is provided for isolation.

Polyimide is layered atop as a sacrificial layer, as shown in FIG. 10A, resulting in an anchor opening and a dimple opening. In FIG. 10B, deposited gold (or other suitable metal) layer, (metal layer two), serves as the movable membrane. The movable membrane is thus in its lifted (device OFF) state after releasing the sacrificial layer.

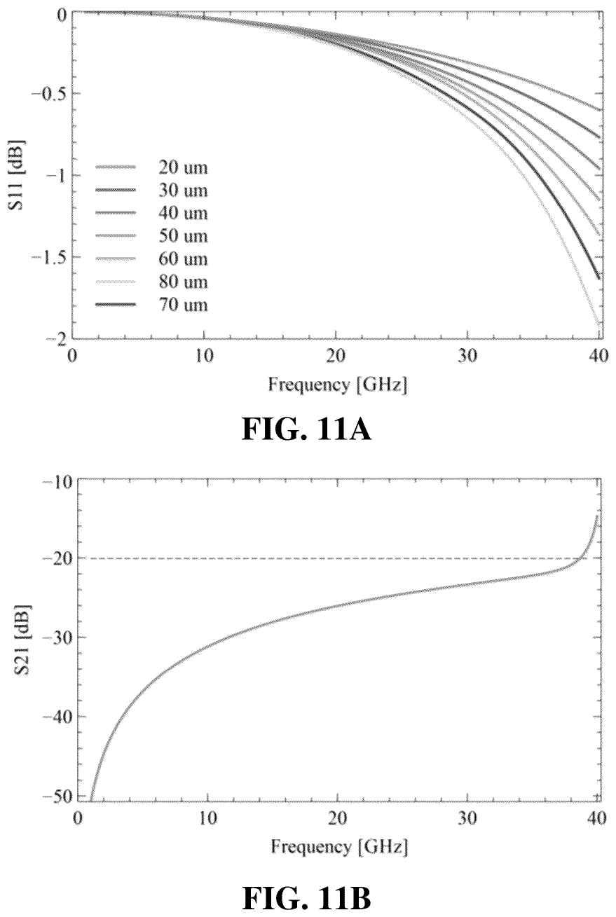

FIGS. 11A and 11B show the RF performance simulation results of one example micro-actuator-based switch device. The return loss, S11, shown in FIG. 11A in dB over DC to 40 GHz, along with the legend in the plot, highlights the multiple simulations for various lengths between two micro-actuators carried out using Ansys HFSS. The isolation performance, S21, shown in FIG. 11B in dB, represents when both micro-actuators are in up-state including the flex from the manufacturing processes; the residual stress in the switch micromembrane is simulated in Ansys Mechanical. As readily apparent in FIG. 11B, the broadband switch operates over DC to 40 GHz with high isolation performance.

One or more example embodiments can be embodied in a device, such as described and represented herein. The device can include a micro-actuator-based switch, including a substrate, a first metallic contact supported by the substrate, and a second metallic contact supported by the substrate. The device can include a first metallic cantilever including an anchored portion and a first non-anchored portion, the first non-anchored portion including a first conductive tip proximate to the first metallic contact, a second metallic cantilever including the anchored portion and a second non-anchored portion, the second non-anchored portion including a second conductive tip proximate to the second metallic contact, wherein the first metallic cantilever can be electrically coupled to the second metallic cantilever, a first electrostatic electrode between the anchored portion and the first non-anchored portion, a second electrostatic electrode between the anchored portion and the second non-anchored portion. A first voltage applied to the first electrostatic electrode bends the first non-anchored portion of the first metallic cantilever towards the substrate to electrically couple the first conductive tip to the first contact. A second voltage applied to the second electrostatic electrode bends the second non-anchored portion of the second metallic cantilever towards the substrate to electrically couple the second conductive tip to the second metallic contact. Application of the first voltage in conjunction with application of the second voltage results in a signal path between the first metallic contact and the second metallic contact. Removal (that is, at least lowering below the actuation voltage) of the first voltage unbends the first non-anchored portion of the first metallic cantilever away from the substrate to electrically decouple the first conductive tip from the first metallic contact, resulting in the first metallic contact and the second metallic contact being electrically isolated from one another.

Removal of the second voltage unbends the second non-anchored portion of the second metallic cantilever away from the substrate to electrically decouple the second conductive tip from the second metallic contact, resulting in increased isolation between the first metallic contact and the second metallic contact relative to a partial actuation state in which the first metallic contact can be electrically isolated from the first conductive tip in conjunction with the second metallic contact being electrically coupled to the second conductive tip.

The first conductive tip can include one conductive tip of a group of first conductive tips, and at least one other conductive tip of the group of first conductive tips can electrically couple to the first metallic contact in response to the first voltage being applied to the first electrostatic electrode.

The first metallic cantilever can be electrically coupled to the second metallic cantilever proximate to the anchored portion via at least one conductive connector.

The first metallic cantilever can be configured as back-to-back with the second metallic cantilever.

The first metallic cantilever can be substantially symmetrical with the second metallic cantilever.

The first metallic cantilever can include a metallic micromembrane.

The first electrostatic electrode can be supported by the substrate.

The device further can include a dielectric that insulates the first electrostatic electrode from the first metallic cantilever.

The first metallic contact can be electrically coupled to a radio frequency (RF) signal input port, and the second metallic contact can be electrically coupled to an RF signal output port.

The switch can be positioned between first and second ground layers supported by the substrate.

The first voltage can be different from the second voltage.

The first electrostatic electrode can be electrically coupled, via a first interconnect, to a first control pad positioned beneath the substrate, and the second electrostatic electrode can be coupled, via a second interconnect, to a second control pad positioned beneath the substrate. The first electrostatic electrode can be coupled to the first control pad through a first resistive element, and the second electrostatic electrode can be coupled to a second control pad through a second resistive element.

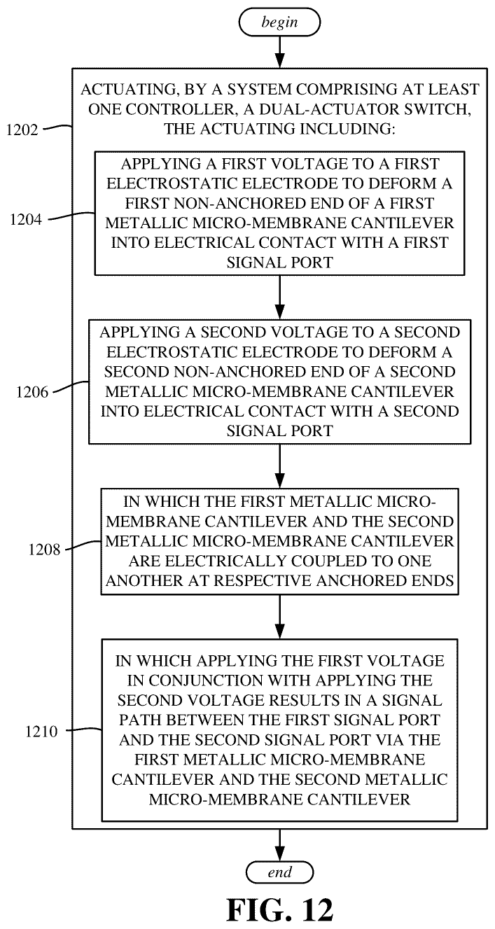

One or more example aspects, such as corresponding to example operations of a method, or a system/a machine-readable medium having executable instructions that, when executed by at least one controller, facilitate performance of the operations, can be represented in FIG. 12. Example operation 1202 represents actuating, by a system including at least one controller, a dual-actuator switch. The actuating can include example operations/blocks 1204 1210. Example operation 1204 represents applying a first voltage to a first electrostatic electrode to deform a first non-anchored end of a first metallic micromembrane cantilever into electrical contact with a first signal port. Example operation 1206 represents applying a second voltage to a second electrostatic electrode to deform a second non-anchored end of a second metallic micromembrane cantilever into electrical contact with a second signal port. Example block 1208 represents that the first metallic micromembrane cantilever and the second metallic micromembrane cantilever can be electrically coupled to one another at respective anchored ends. Example block 1208 represents that applying the first voltage in conjunction with the applying of the second voltage results in a signal path between the first signal port and the second signal port via the first metallic micromembrane cantilever and the second metallic micromembrane cantilever.

Further operations can include de-actuating, by the system, the dual-actuator switch; the de-actuating can include removing the first voltage from the first electrostatic electrode to restore the first non-anchored end of the first metallic micromembrane cantilever into a first non-deformed state that electrically isolates the first non-anchored end from the first signal port, and removing the second voltage from the second electrostatic electrode to restore the second non-anchored end of the second metallic micromembrane cantilever into a second non-deformed state that electrically isolates the second non-anchored end from the second signal port; removing the first voltage in conjunction with removing the second voltage results in electrically isolating the first signal port from the second signal port.

One or more example embodiments can be embodied in a system, such as described and represented herein. The system can include a micro-actuator-based switch, including a substrate, a metallic contact supported by the substrate, a metallic cantilever including an anchored portion and a non-anchored portion, the non-anchored portion including a conductive tip proximate to the metallic contact, and an electrostatic electrode between the anchored portion and the non-anchored portion. A voltage applied to the electrostatic electrode bends the non-anchored portion of the metallic cantilever towards the substrate to electrically couple the conductive tip to the metallic contact. Removal of the voltage applied to the electrostatic electrode unbends the non-anchored portion of the cantilever away from the substrate to electrically decouple the conductive tip from the metallic contact.

The conductive tip can be part of a group including at least two conductive tips proximate to the metallic contact.

The micro-actuator-based switch can be a dual-cantilever switch, the cantilever can be a first cantilever of the dual-cantilever switch, the metallic contact can be a first metallic contact, the non-anchored portion can be a first non-anchored portion, the conductive tip can be a first conductive tip, the electrostatic electrode can be a first electrostatic electrode, the voltage can be a first voltage, and the micro-actuator-based switch further can include a second metallic contact supported by the substrate, a second metallic cantilever of the dual-cantilever switch, the second metallic cantilever including the anchored portion and a second non-anchored portion, the second non-anchored portion including a second conductive tip proximate to the second metallic contact, and the second metallic cantilever electrically coupled to the first metallic cantilever, and a second electrostatic electrode between the anchored portion and the second non-anchored portion. A second voltage applied to the second electrostatic electrode bends the second non-anchored portion of the second metallic cantilever towards the substrate to electrically couple the second conductive tip to the second metallic contact, and removal of the second voltage applied to the second electrostatic electrode unbends the non-anchored portion of the second metallic cantilever away from the substrate to electrically decouple the second conductive tip from the second metallic contact.

The system further can include a controller that controls application of the first voltage in conjunction with application of the second voltage, to result in a signal path between the first metallic contact and the second metallic contact via the first metallic cantilever and the second metallic cantilever.

As can be seen, the technology described herein is directed to a micro-actuator-based switch device and design that reduces/minimizes the amount of actuation voltage by reducing the gap needed to generate adequate pull-in force. This reduces power consumption, making the device energy-efficient for high-performance RF applications.

In one implementation, the device is fabricated as a dual, back-to-back cantilever configuration that increases the isolation performance through increased vertical distance between RF lines and contact points, overcoming the adverse isolation challenges caused by residual stresses post-release of the cantilevers. By using through-substrate interconnects for DC power supply, the design reduces/minimizes any DC to RF interference due to electrostatic actuation, ensuring more consistent control over switch states, appropriate for RF systems that are based on stable operation.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A device, comprising:
a micro-actuator-based switch, comprising:
a substrate;
a first metallic contact supported by the substrate;
a second metallic contact supported by the substrate;
a first metallic cantilever comprising an anchored portion and a first non-anchored portion, the first non-anchored portion comprising a first conductive tip proximate to the first metallic contact;
a second metallic cantilever comprising the anchored portion and a second non-anchored portion, the second non-anchored portion comprising a second conductive tip proximate to the second metallic contact, wherein the first metallic cantilever is electrically coupled to the second metallic cantilever;
a first electrostatic electrode between the anchored portion and the first non-anchored portion; and
a second electrostatic electrode between the anchored portion and the second non-anchored portion,
wherein a first voltage applied to the first electrostatic electrode bends the first non-anchored portion of the first metallic cantilever towards the substrate to electrically couple the first conductive tip to the first contact,
wherein a second voltage applied to the second electrostatic electrode bends the second non-anchored portion of the second metallic cantilever towards the substrate to electrically couple the second conductive tip to the second metallic contact,
wherein application of the first voltage in conjunction with application of the second voltage results in a signal path between the first metallic contact and the second metallic contact, and
wherein removal of the first voltage unbends the first non-anchored portion of the first metallic cantilever away from the substrate to electrically decouple the first conductive tip from the first metallic contact, resulting in the first metallic contact and the second metallic contact being electrically isolated from one another.

2. The device of claim 1, wherein the removal of the second voltage unbends the second non-anchored portion of the second metallic cantilever away from the substrate to electrically decouple the second conductive tip from the second metallic contact, resulting in increased isolation between the first metallic contact and the second metallic contact relative to a partial actuation state in which the first metallic contact is electrically isolated from the first conductive tip in conjunction with the second metallic contact being electrically coupled to the second conductive tip.

3. The device of claim 1, wherein the first conductive tip comprises one conductive tip of a group of first conductive tips, and wherein at least one other conductive tip of the group of first conductive tips electrically couples to the first metallic contact in response to the first voltage being applied to the first electrostatic electrode.

4. The device of claim 1, wherein the first metallic cantilever is electrically coupled to the second metallic cantilever proximate to the anchored portion via at least one conductive connector.

5. The device of claim 1, wherein the first metallic cantilever is configured as back-to-back with the second metallic cantilever.

6. The device of claim 1, wherein the first metallic cantilever is substantially symmetrical with the second metallic cantilever.

7. The device of claim 1, wherein the first metallic cantilever comprises a metallic micromembrane.

8. The device of claim 1, wherein the first electrostatic electrode is supported by the substrate.

9. The device of claim 8, further comprising a dielectric that insulates the first electrostatic electrode from the first metallic cantilever.

10. The device of claim 1, wherein the first metallic contact is electrically coupled to a radio frequency (RF) signal input port, and wherein the second metallic contact is electrically coupled to an RF signal output port.

11. The device of claim 10, wherein the switch is positioned between first and second ground layers supported by the substrate.

12. The device of claim 10, wherein the first voltage is different from the second voltage.

13. The device of claim 1, wherein the first electrostatic electrode is electrically coupled, via a first interconnect, to a first control pad positioned beneath the substrate, and wherein the second electrostatic electrode is coupled, via a second interconnect, to a second control pad positioned beneath the substrate.

14. The device of claim 13, wherein the first electrostatic electrode is coupled to the first control pad through a first resistive element, and wherein the second electrostatic electrode is coupled to a second control pad through a second resistive element.

15. A method, comprising,
actuating, by a system comprising at least one controller, a dual-actuator switch, the actuating comprising:
applying a first voltage to a first electrostatic electrode to deform a first non-anchored end of a first metallic micromembrane cantilever into electrical contact with a first signal port; and
applying a second voltage to a second electrostatic electrode to deform a second non-anchored end of a second metallic micromembrane cantilever into electrical contact with a second signal port,
wherein the first metallic micromembrane cantilever and the second metallic micromembrane cantilever are electrically coupled to one another at respective anchored ends, and
wherein the applying of the first voltage in conjunction with the applying of the second voltage results in a signal path between the first signal port and the second signal port via the first metallic micromembrane cantilever and the second metallic micromembrane cantilever.

16. The method of claim 15, further comprising:
de-actuating, by the system, the dual-actuator switch, the de-actuating comprising:
removing the first voltage from the first electrostatic electrode to restore the first non-anchored end of the first metallic micromembrane cantilever into a first non-deformed state that electrically isolates the first non-anchored end from the first signal port; and
removing the second voltage from the second electrostatic electrode to restore the second non-anchored end of the second metallic micromembrane cantilever into a second non-deformed state that electrically isolates the second non-anchored end from the second signal port,
wherein the removing of the first voltage in conjunction with the removing of the second voltage results in electrically isolating the first signal port from the second signal port.

17. A system, comprising:
a micro-actuator-based switch, comprising:
a substrate;
a metallic contact supported by the substrate;
a metallic cantilever comprising an anchored portion and a non-anchored portion, the non-anchored portion comprising a conductive tip proximate to the metallic contact; and
an electrostatic electrode between the anchored portion and the non-anchored portion,
wherein a voltage applied to the electrostatic electrode bends the non-anchored portion of the metallic cantilever towards the substrate to electrically couple the conductive tip to the metallic contact, and
wherein removal of the voltage applied to the electrostatic electrode unbends the non-anchored portion of the cantilever away from the substrate to electrically decouple the conductive tip from the metallic contact.

18. The system of claim 17, wherein the conductive tip is part of a group comprising at least two conductive tips proximate to the metallic contact.

19. The system of claim 17, wherein the micro-actuator-based switch is a dual-cantilever switch, wherein the cantilever is a first cantilever of the dual-cantilever switch, wherein the metallic contact is a first metallic contact, wherein the non-anchored portion is a first non-anchored portion, wherein the conductive tip is a first conductive tip, wherein the electrostatic electrode is a first electrostatic electrode, wherein the voltage is a first voltage, and wherein the micro-actuator-based switch further comprises:
a second metallic contact supported by the substrate;
a second metallic cantilever of the dual-cantilever switch, the second metallic cantilever comprising the anchored portion and a second non-anchored portion, the second non-anchored portion comprising a second conductive tip proximate to the second metallic contact, and the second metallic cantilever electrically coupled to the first metallic cantilever; and
a second electrostatic electrode between the anchored portion and the second non-anchored portion,
wherein a second voltage applied to the second electrostatic electrode bends the second non-anchored portion of the second metallic cantilever towards the substrate to electrically couple the second conductive tip to the second metallic contact, and
wherein removal of the second voltage applied to the second electrostatic electrode unbends the non-anchored portion of the second metallic cantilever away from the substrate to electrically decouple the second conductive tip from the second metallic contact.

20. The system of claim 17, further comprising a controller that controls application of the first voltage in conjunction with application of the second voltage, to result in a signal path between the first metallic contact and the second metallic contact via the first metallic cantilever and the second metallic cantilever.
